(19) United States
(12) Patent Application Publication
(10) Pub. No.: US 2011/0017255 A1
(43) Pub. Date: Jan. 27, 2011

(54) LED Powered photovoltaic generator

(75) Inventor: Eric Ford Fuller, Kennedale, TX (US)

Correspondence Address: Eric Fuller, P.O. Box 1479, Kennedale, TX, 76060, US

(73) Assignee: Mr. Eric Ford Fuller, Kennedale, TX (US)

(21) Appl. No.: 12/460,662

(22) Filed: Jul. 23, 2009

(51) Int. Cl. H01L 31/042

(52) U.S. Cl. 136/244

(57) ABSTRACT

A device that uses specific dominant wavelength light emitting diode to excite the electrons in photovoltaic cells to produce DC voltage for the purposes of: (a) providing DC voltage to its own light emitting diode system and (b) providing external voltage for an application that requires voltage to operate.

### FIELD OF INVENTION

The present invention relates to a device that provides voltage output to an external application, while providing the internal voltage needs to keep the device operating. This invention takes advantage of photovoltaic cell inefficiencies by removing the needs of direct sunlight and focuses on specific dominant wavelength (color bands) from an light emitting diode that causes the release of electrons in a photovoltaic cell, rather that focusing on full spectrum light.

### BACKGROUND

Present day photovoltaic cells have known inefficiencies that make them impractical and expensive for concurrent use. They work best in unobstructed direct sunlight; which varies from time of day to the various seasons of the year. Batteries are often required to provide voltage to applications when the sunlight is not available. Photovoltaic cells are also known to only absorb specific bands from the full light spectrum making location and atmospheric conditions an issue.

Photovoltaic cells are often arranged into panels of one to several cells in order to realize usable voltage, these panels are often expensive, bulky, and not portable. Although there is the ability to create small portable panels, these continue to fall into the inefficiencies of requiring direct and unobstructed sunlight.

When creating a device with the abilities of potential “always on” or “use when required” one has to remove the need for direct and unobstructed sun light, while providing specific wavelengths from the light band and low voltage requirements for powering the light source.

### SUMMARY OF THE INVENTION

The LED Powered Photovoltaic Generator uses light emitting diodes to broadcast intense specific dominant light waves to excite the electrons in the photovoltaic cells to produce DC wattage. One to several Photovoltaic cells is assembled between highly reflective angled spacers to produce Slave Unit(s) or Power Unit(s). The Slave units are used as the producers of DC wattage supplying the electrical needs to the LED; the Power Unit(s) produce the electrical needs of the external application. An external power supply is needed for the initial start up, and then external voltage is no longer needed for the device to continue producing DC electricity.

### BRIEF DESCRIPTION OF THE DRAWINGS

Having thus described the invention in general terms, reference will now be made to the accompanying drawings, which are not necessarily drawn to scale, and wherein:

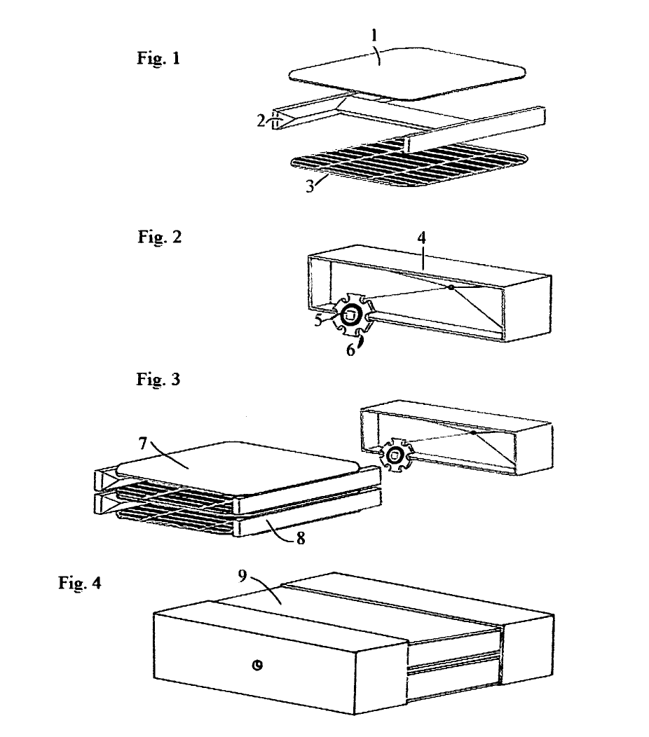

FIG. 1 Photovoltaic Unit (whether Slave or Power): One to many photovoltaic cells sandwiched between a highly reflective specifically angled spacer.
1. Back of Photovoltaic Cell
2. Reflective Spacer
3. Top of photovoltaic Cell

FIG. 2 End Cap Enclosure: One to Several LED(s) is mounted into a highly reflective enclosures design to direct light between Photovoltaic Cells and Spacers.
4. Highly reflective end cap
5. LED mount and Heat sink
6. Light emitting diode

FIG. 3 Power and Slave Unit with End Cap enclosure exploded view
7. Power Unit
8. Slave Unit

FIG. 4 Assembled Units:
9. Assembled Unit

### DETAILED DESCRIPTION OF THE INVENTION

The present inventions now will be described more fully hereinafter with reference to the accompanying drawings, in which some examples of the embodiments of the inventions are shown. Indeed, these inventions may be embodied in many different forms and should not be construed as limited to the embodiments set forth herein; rather, these embodiments are provided by way of example so that this disclosure will satisfy applicable legal requirements. Like numbers refer to like elements throughout.

The LED Powered Photovoltaic Generator is a self sustaining power supply unit that uses specific light waves in the color spectrum to excite electrons in a photovoltaic cell thereby releasing the electrons as DC voltage. The device is comprised of common supplied commercial photovoltaic cells, high intensity specific dominant wavelength light emitting diodes, engineered PVC plastic angled spacers that undergo vacuum metallizing. A LED drivers and DC-DC boosters can also be used to boost lower voltage from the photovoltaic cells to more usable high voltage.

The device is comprised of one to several photovoltaic cells sandwiched between a high reflective spacer to make up a unit. The Units may be a Slave unit or Power Unit, however at least one of each unit is required. The Slave unit produces the electrical needs of the LED system; an external power supply is used for the initial startup of the device's LED(s), once the LED(s) cause the Slave Unit to start producing the electrical needs the external power supply ceases to be required. The Power Unit produces the electrical needs of the application; this unit can be used with a DC-DC booster to take low output voltage from the Power Unit and boost it to more useful higher voltage.

The device is portable and does not require any assistance from the Sun, wind, or water nor requires recharging, or plugging into an outlet. Once started it operates for several thousand hours until the internal parts reach their specified lifespan. The device is scalable and intended for use with an application or electrical device requiring DC power direct at the source or inverted into AC power through a DC-AC inverter.

FIG. 1 describes the components of a Photovoltaic Unit. It is composed of one to several photovoltaic cells with top surfaces facing each other sandwiched between highly reflective precisely angled surfaces. The spacer creates a cavity between the two photovoltaic cells to allow the passing and directing of the light wave provided by the LED. These Units can be wired together in series or in parallel to achieve the voltage and/or current requirements of any given application. One too many units can be used together to create either the Slave Unit or the Power Unit. Typical Photovoltaic cells can produces higher Amps at very low Voltage, Adjustable DC-DC boosters can be used to take low voltage to a more usable higher voltage.

FIG. 2 describes the End Cap Enclosure of the device. One to Two enclosures are used to hold the LED and its heat sink. The high reflective and precisely angled inside surface is used to direct light waves into the Photovoltaic Units described in FIG. 1. The End Cap Enclosures fit over the Photovoltaic Units allowing minimal light waves to escape and provide some rigidity to otherwise fragile photovoltaic cells.

FIG. 3 describes the lining up of the parts of the invention. In this example one Slave Unit and one power unit are stacked together and the end cap containing the LED slides over the end of the Units to contain them and prevent lose of light waves.

FIG. 4 describes an example of the invention using two End Cap Enclosures, with one Power and one Slave Unit.

Many modifications and other embodiments of the inventions set forth herein will come to mind to one skilled in the art to which these inventions pertain having the benefit of the teachings presented in the foregoing descriptions and the associated drawings. Therefore, it is to be understood that the inventions are not to be limited to the specific examples of the embodiments disclosed and that modifications and other embodiments are intended to be included within the scope of the appended claims. Although specific terms are employed herein, they are used in a generic and descriptive sense only and not for purposes of limitation.

What I claim is:

1. This invention is an enclosed device that uses few to many parts to produce DC electrical voltage from photovoltaic cells and light emitting diode.

2. This device is configured to be self powered once an initial “start up” external voltage source is applied.

3. This device will produce DC voltage for applications needing an external DC voltage source

4. The device can be used with an inverter to convert DC voltage to AC voltage
